(19) United States
(12) Patent Application Publication
(10) Pub. No.: US 2009/0273079 A1
(43) Pub. Date: Nov. 5, 2009

(54) SEMICONDUCTOR PACKAGE HAVING PASSIVE COMPONENT BUMPS

(75) Inventor: J. Thomas Lovskog, Kavlinge (SE)

Correspondence Address: WARREN A. SKLAR (SOER);RENNER, OTTO, BOISSELLE & SKLAR, LLP, 1621 EUCLID AVENUE, 19TH FLOOR, CLEVELAND, OH, 44115, US

(73) Assignee: SONY ERICSSON MOBILE COMMUNICATIONS AB, Lund (SE)

(21) Appl. No.: 12/245,453

(22) Filed: Oct. 3, 2008

Related U.S. Application Data
(60) Provisional application No. 61/050,469, filed on May 5, 2008.

(51) Int. Cl. H01L 23/48; H05K 1/00

(52) U.S. Cl. 257/737; 174/267; 257/E23.01

(57) ABSTRACT

A semiconductor package includes contact bumps configured as passive circuit components. One or more contact bumps of the semiconductor package may be formed or configured as pull-up resistors, pull-down resistors, capacitors or inductors.

### RELATED APPLICATION DATA

The present application claims the benefit of U.S. Provisional Application Ser. No. 61/050,469, filed May 5, 2008, the disclosure of which is herein incorporated by reference in its entirety.

### TECHNICAL FIELD OF THE INVENTION

The present invention relates generally to semiconductor packages, and more particularly, to a semiconductor package having contact bumps configured as passive components.

### DESCRIPTION OF RELATED ART

Semiconductor packages, such as chip scale packages (CSPs) and ball grid arrays (BGAs), continue to grow in popularity to reduce the size and weight of electronic equipment, e.g., mobile phones and other portable communication devices. CSPs and BGAs typically include a package or an assembly of packages having integrated circuits, insulating layers and internal wiring. Contact balls or bumps, e.g., solder bumps, are used to conduct electrical signals from the integrated circuits to a printed circuit board on which the CSP or BGA is mounted. Typically, the CSP or BGA is mounted or otherwise electrically coupled to copper pads on the printed circuit board.

The CSP or BGA typically is connected to power supplies and ground through one or more passive components. Such passive components include, for example, pull-up resistors, pull-down resistors, capacitors and inductors. In some conventional configurations, the passive components are positioned outside of the CSP or BGA. For example, a portion of the circuitry within the CSP or BGA may be connected to a power supply and an external pull-up resistor through at least one contact bump by way of extra routing or internal wiring within the semiconductor package and/or the printed circuit board.

### SUMMARY

A semiconductor package includes one or more contact bumps configured as passive circuit components. The provision of a semiconductor package having contact bumps configured as passive circuit components may provide a simplified overall design and reduced routing or wiring requirements.

One aspect of the disclosed technology relates to a semiconductor package that includes a package body including insulating layers and circuit components, and a plurality of contact bumps electrically coupled to the circuit components, wherein a plurality of the contact bumps are configured as passive circuit components.

According to another feature, at least one of the contact bumps is configured as a resistor having a predetermined value.

According to another feature, at least one of the contact bumps is configured as a capacitor having a predetermined value.

According to another feature, at least one of the contact bumps is configured as a pull-up resistor having a predetermined value.

According to another feature, at least one of the contact bumps is configured as a pull-down resistor having a predetermined value.

According to another feature, at least one of the contact bumps is configured as a series resistor having a predetermined value.

According to another feature, at least one of the contact bumps is configured as an inductor having a predetermined value.

According to another feature, the semiconductor package comprises at least three-hundred contact bumps and at least one-hundred of the contact bumps are configured as passive circuit components having predetermined values.

According to another feature, a plurality of the at least one-hundred contact bumps are formed as resistors having predetermined values.

According to another feature, a plurality of the at least one-hundred contacts bumps are formed as capacitors having predetermined values.

According to another feature, a plurality of the at least one-hundred contact bumps are formed as capacitors having predetermined values.

According to another feature, the semiconductor package is electrically coupled to a printed circuit board, the printed circuit board having a plurality of contact pads in a predetermined pattern, wherein the contact bumps of the semiconductor package are arranged in the predetermined pattern.

Another feature relates to a portable communication device including the above-described semiconductor package.

According to another feature, the portable communication device is a mobile telephone.

Another aspect of the disclosed technology relates to a circuit board including a main board and a plurality of contact pads arranged in a predetermined pattern and configured to electrically couple to contact bumps of an associated semiconductor package, wherein a plurality of the contact pads are configured as passive circuit components.

According to another feature, a plurality of the contact pads are configured as pull-up resistors.

According to another feature, a plurality of the contact pads are configured as pull-down resistors.

According to another feature, a plurality of the contact pads are configured as capacitors.

These and further features of the present invention will be apparent with reference to the following description and attached drawings. In the description and drawings, particular embodiments of the invention have been disclosed in detail as being indicative of some of the ways in which the principles of the invention may be employed, but it is understood that the invention is not limited correspondingly in scope. Rather, the invention includes all changes, modifications and equivalents coming within the spirit and terms of the claims appended thereto.

Features that are described and/or illustrated with respect to one embodiment may be used in the same way or in a similar way in one or more other embodiments and/or in combination with or instead of the features of the other embodiments.

It should be emphasized that the term “comprises/comprising” when used in this specification is taken to specify the presence of stated features, integers, steps or components but does not preclude the presence or addition of one or more other features, integers, steps, components or groups thereof.

### BRIEF DESCRIPTION OF DRAWINGS

Many aspects of the invention can be better understood with reference to the following drawings. The components in the drawings are not necessarily to scale, emphasis instead being placed upon clearly illustrating the principles of the present invention. Likewise, elements and features depicted in one drawing may be combined with elements and features depicted in additional drawings. Moreover, in the drawings, like reference numerals designate corresponding parts throughout the several views.

FIG. 1 is a diagrammatic illustration of a portion of a semiconductor package having conventional contact bumps and external passive components;

FIG. 2 is a diagrammatic illustration of a portion of a semiconductor package in accordance with one aspect of the disclosed technology;

FIG. 3 is a diagrammatic illustration of a portion of a semiconductor package in accordance with an exemplary embodiment of the disclosed technology;

FIG. 4 is a diagrammatic illustration of a portion of a semiconductor package in accordance with another exemplary embodiment of the disclosed technology;

FIG. 5 is a diagrammatic illustration of a portion of a semiconductor package and a printed circuit board in accordance with another exemplary embodiment of the disclosed technology;

FIG. 6 is a diagrammatic illustration of a portion of a semiconductor package in accordance with another exemplary embodiment of the disclosed technology; and

FIG. 7 is a diagrammatic illustration of a mobile phone as an exemplary portable communication device in which a semiconductor package is employed.

### DETAILED DESCRIPTION OF EMBODIMENTS

In the detailed description that follows, like components have been given the same reference numerals regardless of whether they are shown in different embodiments of the present invention. To illustrate the present invention in a clear and concise manner, the drawings may not necessarily be to scale and certain features may be shown in somewhat schematic form.

Many semiconductor packages, e.g., chip scale packages (CSPs) and ball grid arrays (BGAs), include integrated circuits that are connected to a power supply or ground through one or passive components, e.g., pull-up resistors, pull-down resistors, capacitors and inductors. In some conventional configurations, the passive components are positioned outside the CSP or BGA. For example, a portion of the circuitry within the CSP or BGA may be connected to a power supply and an external pull-up resistor through at least one contact bump by way of extra routing or internal wiring. This type of configuration often introduces extra complexity for the extra routing and/or internal wiring. In addition, the provision of external passive components takes up additional space.

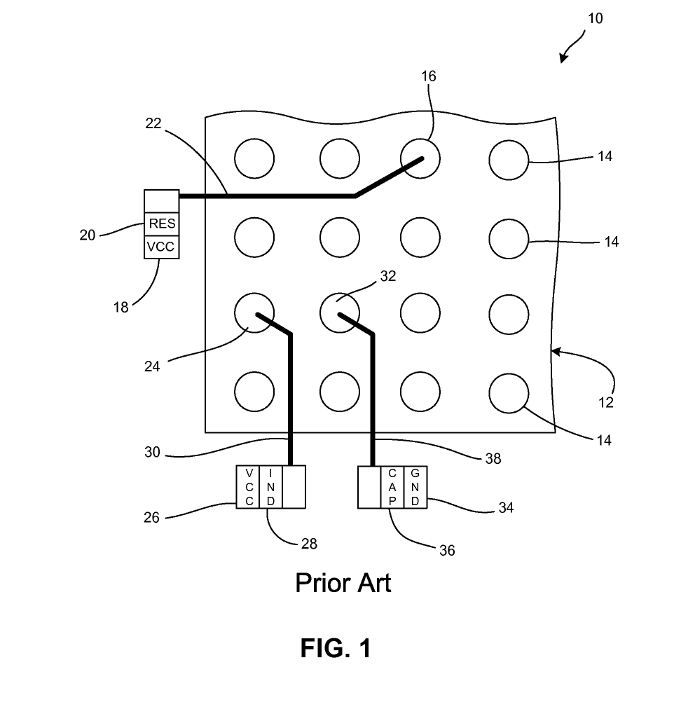

FIG. 1 shows a conventional a conventional semiconductor package 10 with a conventional configuration in which the semiconductor package is connected to a power supply and ground by way of external passive components. It will be appreciated that the semiconductor package 10 may be a chip scale package (CSP), e.g., a wafer-level CSP or a wafer level package, a ball grid array (BGA) or any other semiconductor package in which integrated circuits are formed in a package that is connected to a printed circuit board by contact bumps, pads or pins (designated generally by reference numeral 14).

The semiconductor package 10 may include a substrate and one or more layers (referred to generally as by reference numeral 12), e.g., insulating layers, formed on or adjacent the substrate. The intermediate layers may include or otherwise support a variety of integrated circuits and circuit components, internal wiring and the like.

The exemplary semiconductor package depicted in FIG. 1 includes a plurality of contact bumps or pads electrically coupled by wiring within the semiconductor package to voltage sources and/or ground through passive components that are external to the semiconductor package 10. For example, contact bump 16 is electrically coupled to a power supply (VCC) 18 through resistor (RES) 20 via wiring 22. Also contact bump 24 is electrically coupled to a power supply (VCC) 26 through inductor 28 via wiring 30. Further, contact bump 32 is electrically coupled to ground (GND) 34 through capacitor 36 via wiring 38.

The present disclosure recognizes shortcomings with conventional semiconductor package configurations, such as the exemplary configuration of FIG. 1, in which extra wiring or routing is used to connect to external passive circuit components. The complexity of wiring associated with convention designs is compounded when considering a semiconductor package including hundreds of contact bumps, with many of these bumps having wiring to provide electrical coupling to external passive circuit components (or even passive circuit components disposed within insulating layers of the semiconductor package). The present disclosure provides a semiconductor package having contact bumps configured as passive circuit components. The provision of contact bumps being configured as passive circuit components allows for overall space savings and the reduction of internal and/or external wiring or routing.

It will be further appreciated that the semiconductor package described below may be employed in connection with a variety of types of electronic equipment, including, but not limited to, mobile telephones, pagers, communicators, i.e., electronic organizers, smartphones, personal digital assistants (PDAs), or the like.

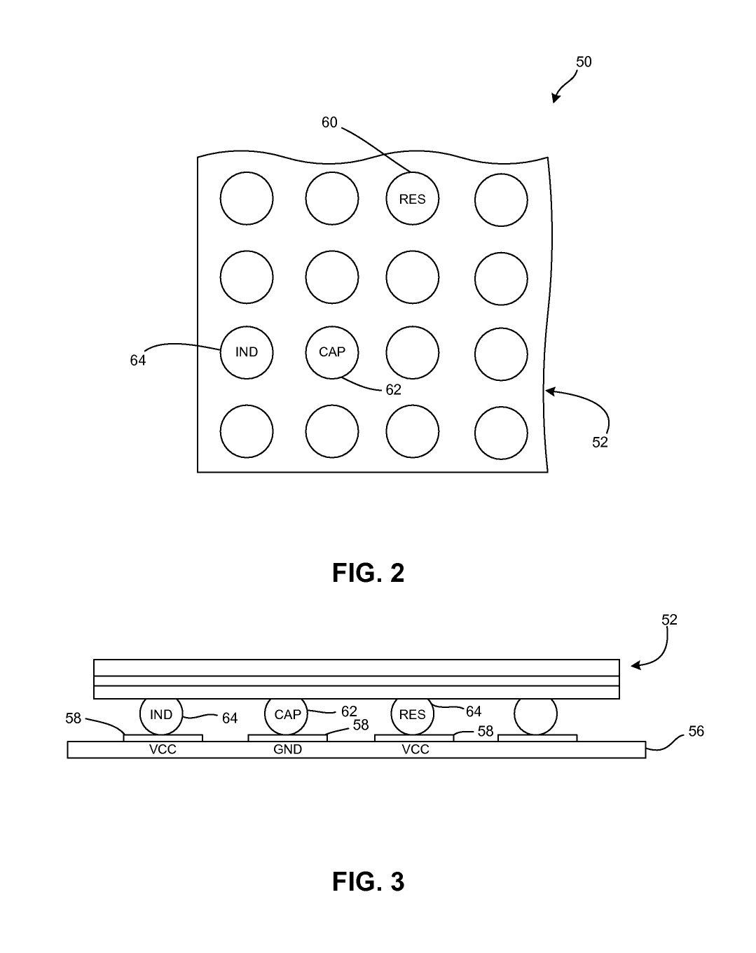

Turning now to FIGS. 2 and 3, an exemplary embodiment of a portion of a semiconductor package 50, e.g., a chip scale package (CSP) or a ball grid array (BGA) is depicted. The semiconductor package 50 includes a main package body (designated generally with reference numeral 52), which may include a variety of insulating layers and circuit components. For example, the main package body 52 may include one or more semiconductor layers on which various circuit and/or semiconductor components are formed as well as a variety of insulating layers and suitable connectors between the various layers. It will be appreciated that aspects of the disclosed technology described herein are not limited to any particular package geometry or configuration. Rather, the disclosed technology may be employed in connection with any semiconductor package in which integrated circuits are electrically coupled to a printed circuit board or other suitable support member via contact bumps, pads or pins.

The semiconductor package 50 includes a plurality of contact bumps (designated generally with reference numeral 54). While the semiconductor package is being described with respect to contact bumps, it will be appreciated that other bump or contact geometries may be employed without departing from the scope of the present invention.

As is shown in FIG. 3, the various bumps of the semiconductor package are used or otherwise configured to make contact with a printed circuit board 56, typically by making electrical contact with a plurality of contact pads 58, e.g., copper contact pads, disposed on the printed circuit board in a predetermined fashion. In accordance with a preferred embodiment, at least several of the contact bumps will be formed or otherwise configured as passive circuit components. For example, in the embodiment illustrated in FIG. 2 and FIG. 3, one contact pad 60 is configured as a resistor (RES), e.g., a pull-up resistor, a pull-down resistor or a series resistor. Another contact bump 62 is configured as or otherwise formed as a capacitor (CAP). In the illustrated exemplary embodiment, another contact bump 64 is configured as an inductor (IND). It will be appreciated that the configuration of FIG. 3 is provided as an example, and the various contact bumps 62, 64 may be configured as resistors, capacitors or inductors without departing from the scope of the present invention.

As shown in FIG. 3, the semiconductor package may be configured such that various passive circuit component bumps are arranged or otherwise configured to be electrically coupled to or otherwise in contact with printed circuit board contact pads 58 to connect the various bumps to, for example, a power supply (VCC) or ground (GND). It will be appreciated that the semiconductor package configuration in which some of the contact bumps are formed as passive circuit components provide advantages over the conventional semiconductor package described above with respect to FIG. 1. For example, the provision of contact bumps being configured as passive circuit components allows for a more direct connection (e.g., shorter leads and improved electrical performance) between the contact bump and a power supply or ground because the external wiring shown in FIG. 1 is no longer used to make contact between the semiconductor package and a power supply or ground through an external passive circuit component. Also, the design depicted in FIGS. 2 and 3 generally minimizes the need for external passive circuit components connected between a semiconductor package and a power supply or ground. The reduction of extra wiring or routing may also allow for fewer routing or wiring layers in the printed circuit board itself and/or in the semiconductor package.

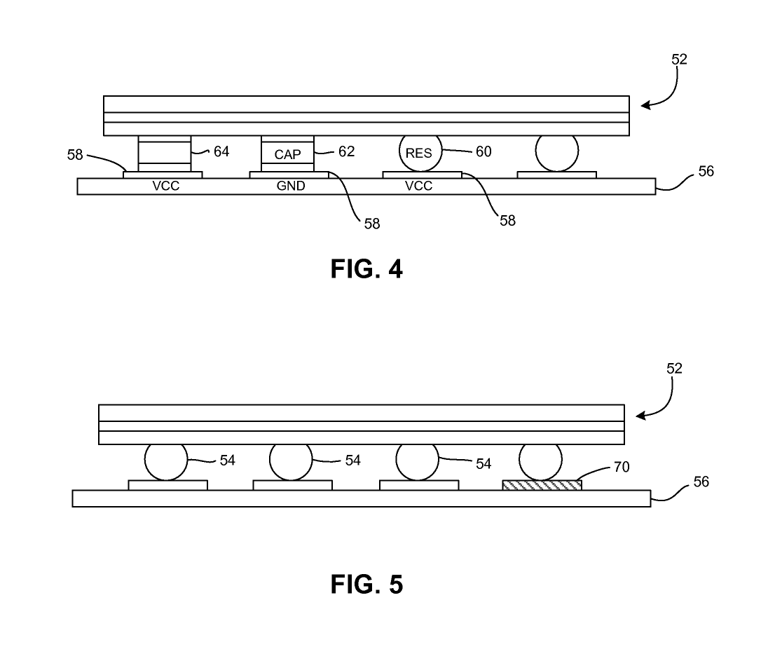

In one embodiment, the contact bumps that are configured as passive circuit components may have a geometry similar to the geometry of conventional contact bumps. For example, the passive circuit component contact bumps may be configured as a conventional solder bump, only being made of a different material or materials. Alternatively, as shown in FIG. 4, the passive circuit component bump may be configured more as a stack, e.g., a package on package (PoP) stack which may be particularly useful for contact bumps being configured as capacitors.

It will be appreciated that the passive circuit component contact bumps may be made of a variety of materials and in a variety of different manners depending on the particular circuit component being formed. For example, while a conventional contact bump may be comprised of a highly conductive material, e.g., a material having a rather low resistivity, such as a tin or lead solder ball, the contact bump described herein may made out of a material having a greater resistivity such that the contact bump has a predetermined resistance value that makes it suitable to function as, for example, a pull-up resistor, a pull-down resistor or a series resistor.

While the passive circuit component contact bumps are shown as being disposed between the CSP and the printed circuit board, it will be appreciated that other configurations may be employed without departing from the scope of the present invention. For example, if a particular passive component is too large to fit between the CSP and the printed circuit board, the passive circuit component contact bumps may be disposed between the CSP and an inner layer in a recess of the printed circuit board.

FIG. 5 illustrates another exemplary embodiment in which the contact pad of the printed circuit board may be configured as a passive circuit component, e.g., as a pull-up resistor, a pull-down resistor or a capacitor. For example, contact pad 70 may be configured to have a resistive surface finish such that the contact pad has a resistance that would typically be employed for a pull-up resistor or a pull-down resistor. Alternatively, the contact pad may be comprised of a material having a higher resistivity than that normally found in a copper contact pad. Further, contact pads on the printed circuit board may be configured in other ways such that they are formed as capacitors or other passive circuit components. It will be appreciated that this design may also be combined with the design embodiments shown in FIGS. 2-4 without departing from the scope of the present invention. That is, it is possible to combine various passive circuit component formation techniques such that the passive circuit components are integrated into the contact bumps alone or in combination with the contact pads of the printed circuit board.

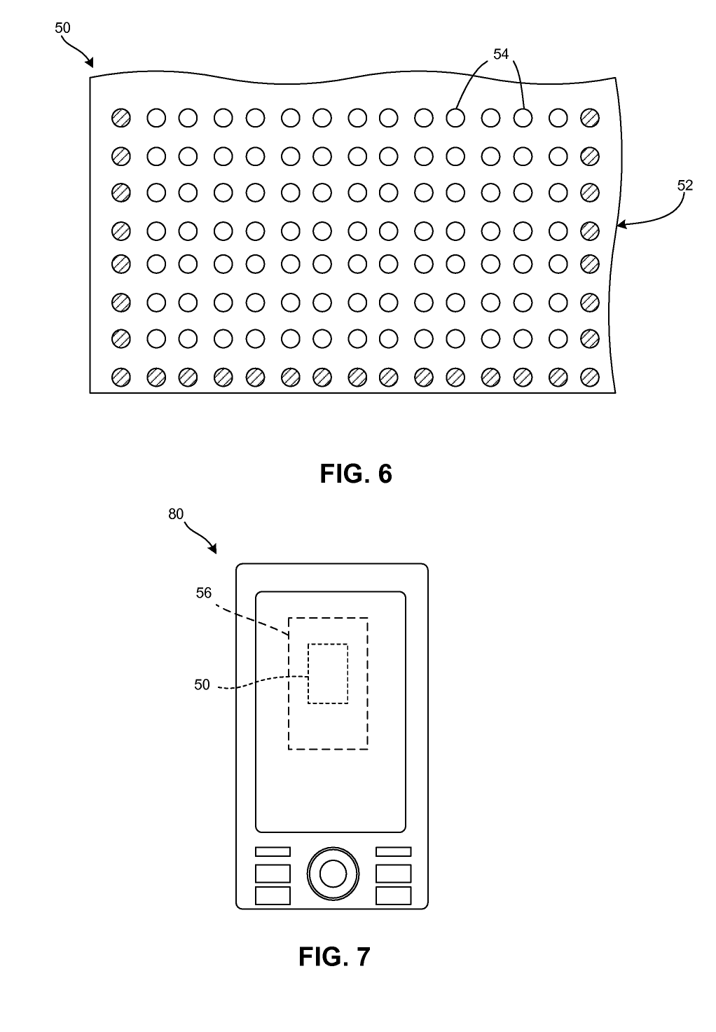

It will be appreciated that the provision of contact bumps or contact pads configured as passive circuit components provides space saving as well as wiring and routing savings in the semiconductor package and/or in the printed circuit board on which the semiconductor package is mounted. While the exemplary embodiments shown in FIGS. 2-5 illustrate a relatively small number of contact bumps, it will be appreciated that the space and routing savings can be substantial, especially in light of semiconductor packages having hundreds, (e.g., three-hundred, four-hundred, five-hundred, six-hundred or more) contact bumps. In this regard, FIG. 6 shows a portion of a semiconductor package having a larger number of contact bumps. In a conventional semiconductor package design having such a large number of contact bumps, a relatively large number of passive components may be disposed around or adjacent the edges of the semiconductor package. For example, a conventional semiconductor package may have two or three rows around the edges of the package substantially electrically coupled to various passive circuit components. This can make it difficult to sample or otherwise receive other signals out of the semiconductor package. This, in turn may require the movement of signals up and/or down various layers of the semiconductor package in order to obtain the signals out of the semiconductor package. In contrast, the exemplary semiconductor package shown in FIG. 6 may have one, two, three or more rows of contact pads configured as passive circuit components, thereby allowing for more space to sample or otherwise get signals from different portions of the semiconductor package, again, resulting in substantial savings of overall space and wiring or routing.

It will be appreciated that the semiconductor package described above may be employed with a various types of electronic equipment. For example, FIG. 7 illustrates use of a suitable semiconductor package 50 having contact bumps configured as passive circuit components mounted to printed circuit board 56 within a portable communication device 80, e.g., a mobile phone.

The provision of a semiconductor package having contact bumps configured as passive circuit components may provide numerous benefits. For example, this design may be more compact and less complex due to the reduction in external passive circuit components as well as the reduction of extra wiring and routing to connect various bumps to external passive circuit components (or internal passive circuit components disposed within various insulating layers of the semiconductor package. Because the passive circuit component contact bumps are connected directly to ground or a power supply, a more compact design is achieved, which may allow for use of the semiconductor package in devices where reduced size and weight is important. The semiconductor package may result in improved electrical performance because the leads are shorter.

Although the invention has been shown and described with respect to a certain preferred embodiment or embodiments, it is obvious that equivalent alterations and modifications will occur to others skilled in the art upon the reading and understanding of this specification and the annexed drawings. In particular regard to the various functions performed by the above described elements (components, assemblies, devices, compositions, etc.), the terms (including a reference to a “means”) used to describe such elements are intended to correspond, unless otherwise indicated, to any element which performs the specified function of the described element (i.e., that is functionally equivalent), even though not structurally equivalent to the disclosed structure which performs the function in the herein illustrated exemplary embodiment or embodiments of the invention. In addition, while a particular feature of the invention may have been described above with respect to only one or more of several illustrated embodiments, such feature may be combined with one or more other features of the other embodiments, as may be desired and advantageous for any given or particular application.

1. A semiconductor package comprising:
a package body including insulating layers and circuit components; and
a plurality of contact bumps electrically coupled to the circuit components;
wherein a plurality of the contact bumps are configured as passive circuit components.

2. The semiconductor package of claim 1, wherein at least one of the contact bumps is configured as a resistor having a predetermined value.

3. The semiconductor package according to claim 1, wherein at least one of the contact bumps is configured as a capacitor having a predetermined value.

4. The semiconductor package of claim 1, wherein at least one of the contact bumps is configured as a pull-up resistor having a predetermined value.

5. The semiconductor package of claim 1, wherein at least one of the contact bumps is configured as a pull-down resistor having a predetermined value.

6. The semiconductor package of claim 1, wherein at least one of the contact bumps is configured as a series resistor having a predetermined value.

7. The semiconductor package of claim 1, wherein at least one of the contact bumps is configured as an inductor having a predetermined value.

8. The semiconductor package of claim 1, wherein the semiconductor package comprises at least three-hundred contact bumps and at least one-hundred of the contact bumps are configured as passive circuit components having predetermined values.

9. The semiconductor package of claim 8, wherein a plurality of the at least one-hundred contact bumps are formed as resistors having predetermined values.

10. The semiconductor package of claim 8, wherein a plurality of the at least one-hundred contacts bumps are formed as capacitors having predetermined values.

11. The semiconductor package of claim 8, wherein a plurality of the at least one-hundred contact bumps are formed as capacitors having predetermined values.

12. The semiconductor package of claim 1 electrically coupled a printed circuit board, the printed circuit board having a plurality of contact pads in a predetermined pattern, wherein the contact bumps of the semiconductor package are arranged in the predetermined pattern.

13. A portable communication device comprising the semiconductor package of claim 1.

14. The portable communication device of claim 13, wherein the portable communication device is a mobile telephone.

15. A printed circuit board comprising a main board and a plurality of contact pads arranged in a predetermined pattern and configured to electrically couple to contact bumps of an associated semiconductor package, wherein a plurality of the contact pads are configured as passive circuit components.

16. The printed circuit board of claim 15, wherein a plurality of the contact pads are configured as pull-up resistors.

17. The printed circuit board of claim 15, wherein a plurality of the contact pads are configured as pull-down resistors.

18. The printed circuit board of claim 15, wherein a plurality of the contact pads are configured as capacitors.
